(19) United States
(12) Patent Application Publication
(10) Pub. No.: US 2012/0192741 A1
(43) Pub. Date: Aug. 2, 2012

(54) METHOD FOR PREPARING LITHOGRAPHIC PRINTING PLATES

(76) Inventor: MOSHE NAKASH, Ramat Hashron (IL)

(21) Appl. No.: 13/017,111

(22) Filed: Jan. 31, 2011

(51) Int. Cl. G03F 7/20; B41N 1/00

(52) U.S. Cl. 101/453; 430/302

(57) ABSTRACT

Lithographic printing plates can be prepared and made ready for lithographic printing with simple wet development or processing. A positive-working lithographic printing plate precursor is exposed to infrared radiation for example at 200 to 300 mJ/cm². The exposed precursor can be simply processed with water or an aqueous solution, and uniformly exposed to radiation, heat, or both. The positive-working lithographic printing plate precursor has a hydrophilic aluminum substrate, a crosslinked hydrophilic inner layer, and an oleophilic surface layer that is weakly bonded to the crosslinked hydrophilic inner layer.

### FIELD OF THE INVENTION

This invention relates to a method for preparing lithographic printing plates from positive-working lithographic printing plate precursors having an oleophilic surface layer that is imageable by infrared radiation, which layer is disposed over and adhered to a crosslinked hydrophilic layer.

### BACKGROUND OF THE INVENTION

Offset lithographic printing has remained important in many areas of printing for several reasons. For continual printing methods, offset lithography has provided simplicity, cost-effectiveness, and high print quality.

Modern technology permits the generation of all kinds of digital data including images, text, and collections and arrangements of data in personal computers or other storage devices in a way that is useful in the generation of printed copy. The data are then directed to a CTP (Computer-to-Plate) device where it is used to modulate a laser (or array of lasers) that “writes” the digital data onto lithographic printing plate precursors. The resulting latent images in the precursors generally require wet processing in a developer to differentiate the regions that will accept ink from the background regions that reject ink during the printing process.

The concept of using laser energy to digitally image printing plates has closely followed the development of lasers. Early lasers were powerful but slow and expensive. U.S. Pat. No. 3,574,657 (Burnett) describes the use of a thermally crosslinked resin on a hydrophilic aluminum substrate that is imaged by thermal laser removal of the resin. Early imaging using lasers was slower than existing chemical etching techniques. The laser power required at a given spot was quite high and the heat generated was also high. The material had to be completely vaporized for an interval sufficient to ensure its removal. Consequently, there was a great quantity of thermal energy transferred to the surrounding area that had to be removed before another spot could be etched. Clearly, the art had not progressed to the level where the thermal energy could be removed quickly enough to enable laser etching to compete in speed with chemical etching. In addition to slow production, the printing plates produced images that were unacceptably irregular and lacking in definition. A suitable exposure system would use argon ion, helium-cadmium, and other lasers of like nature to image commercially available diazo-sensitized layers on aluminum supports. The imaged printing plates were processed using a developer.

U.S. Pat. No. 4,020,762 (Peterson) describes the use of a YAG laser to remove non-image areas, and the imaged areas were then exposed to UV light and developed using an additive developer.

U.S. Pat. No. 4,054,094 (Caddell et al.) describes the imaging of a lithographic printing plate precursor that has an aluminum base coated with a hydrophilic coating using a laser to burn away the coating and causing the aluminum surface to become oleophilic in the imaged areas leaving hydrophilic areas of the substrate. Such laser “burning” has become known as laser ablation.

An additional approach to simplification of the offset lithographic printing process is described in U.S. Pat. No. 3,511,178 (Curtin) in which the concept of waterless printing was introduced by using printing plate precursors coated with polydimethyl siloxane (silicone) that preferentially rejected ink during printing and formed the areas corresponding to the background. GB Patent Publication 1,489,308 (Eames) combined the ideas of waterless printing and laser ablation.

U.S. Pat. No. 4,693,958 (Schwartz et al.) describes use of a specific range of hydrophilic polymers curable to hydrophobic material using an infrared laser and then washing off the uncured non-imaged background regions using water or a neutral or alkaline solution.

Although the concepts described in this art were useful, in practice they created a number of problems that were not evident until later. They are expensive, slow, and require high power as described in U.S. Pat. No. 5,339,737 (Lewis et al.). U.S. Pat. No. 5,605,780 (Burberry et al.) describes the use of a poly(cyanoacrylate) imaging layer on hydrophilic aluminum that is ablatable using an array of lower-powered lasers.

A significant advantage of using laser ablation for imaging is that as the ablated material is destroyed there is minimal development or wet processing needed after imaging. Development can be carried out using a wet processing solution or wet development can be omitted. Conventional lithographic printing plate making generally requires formulated processing solutions for development to wash away material in the background regions of the imaged printing plate. These processing solutions can be unstable and during use they become contaminated with the removed material so that they require replenishment or regeneration on a periodic basis.

Ideally, imaging by ablation should require no such processing solutions but in practice this is not the case. For instance, in U.S. Pat. No. 5,339,737 (noted above), ablated material can be cleaned using only a rotating brush.

There have been many attempts to simplify processing of imaged lithographic printing plate precursors. Some imaged precursors can be processed on-press using the lithographic printing chemicals. Other processing techniques include the mere use of water, and these techniques are sometimes called “simplified processing”.

A problem with these “simplified” processing methods is that it is difficult to achieve long run lengths comparable to those imaged precursors that are designed for development using alkaline developers. This type of processing is believed to be beneficial when printing is carried out using an acidic fountain solution so that the adverse effects of the fountain solution are minimized by the alkaline processing developers.

U.S. Pat. No. 4,731,317 (Fromson) may suggest that laser imaging of lithographic printing plate precursors can reduce the solubility of the imageable layers. However, there must still be a suitable amount of adhesion between the oleophilic image regions and the underlying substrate. Where the difference between exposed and non-exposed regions is achieved by differences in adhesion between the layers, the imaging process either loosens the bond between the imageable layer and substrate so that background regions are easily removed (positive-working), or the heat from imaging causes the imageable layer to more closely bond to the substrate so that the non-exposed regions can be removed during processing (negative-working). In either instance, it is difficult to achieve long run length when there is a need to optimize the difference between highly adhered regions and weakly adhered regions.

U.S. Pat. No. 6,490,975 (Rorke et al.) describes infrared radiation imaging that makes the imageable layer of the precursors removable with water or another processing solution. However, if the imageable layer is too strongly bound to the underlying layer or substrate, it is difficult to loosen it sufficiently during imaging to remove the imaged regions with water (simplified processing). In contrast, if the imageable layer is loosely bound to the underlying layer or substrate, non-exposed regions are too easily removed during lithographic printing.

There is a need to avoid the problems described above. Specifically, it is desired to use simplified processing, for example, with mere water or weakly alkaline solutions to remove imaged regions while the non-imaged regions maintain good adhesion to underlying layers or substrate to provide long run length.

### SUMMARY OF THE INVENTION

This invention provides a method for providing a lithographic printing plate comprising:
providing a positive-working lithographic printing plate precursor comprising a hydrophilic substrate and having thereon:
   a crosslinked hydrophilic inner layer, and
   disposed over the crosslinked hydrophilic layer, an oleophilic surface layer comprising at least one non-crosslinked oleophilic polymer and an infrared radiation absorber in an amount of at least 2 weight %,
imagewise exposing the positive-working lithographic printing plate precursor with infrared radiation to form an imaged precursor with exposed regions and non-exposed regions in the oleophilic surface layer,
processing the imaged precursor to remove the oleophilic surface layer in the exposed regions, and
blanket exposing the imaged precursor to radiation.

This invention also provides a lithographic printing plate obtained by a method of this invention, the lithographic printing plate comprising a hydrophilic substrate and having thereon:
a crosslinked hydrophilic inner layer, and
disposed directly on the crosslinked hydrophilic layer, an oleophilic surface layer comprising non-exposed regions comprising at least one non-crosslinked oleophilic polymer and an infrared radiation absorber in an amount of at least 2 weight %, and exposed regions that are formed by removal of the oleophilic surface layer down to the crosslinked hydrophilic inner layer.

This invention provides a method for improving the run length of lithographic printing plates that are prepared from positive-working precursors that have two essential layers, and upon laser exposure, the adhesion between the essential layers is reduced so that mere water can be used to remove exposed regions in the topmost layer. The layers in the precursors are not generally ablated during exposure but the laser-imaged regions can be very easily removed with water or a simple aqueous solution, or with on-press printing solutions, with no pre-development treatment. Unexpectedly, laser-exposed regions are easily removed while the non-exposed oleophilic regions in the printing plate have improved adhesion so they are not readily removed. This improvement is achieved by using a blanket exposure of the imaged and processed precursor to radiation that can be UV or IR radiation or convection heating. The resulting lithographic printing plate has high resistance to solvents and exhibits long run length without image quality deterioration. In addition, such lithographic printing plates can be stored without a need for gumming after imaging and processing.

To achieve these advantages, the precursor is purposely constructed to have relatively poor adhesion between the oleophilic surface layer and a crosslinked hydrophilic inner layer. Laser-imaging then decreases the resistance of the oleophilic surface layer to water processing sufficiently to leave an intact, full, and sharp image. Subsequent exposure of the processed precursor to blanket or uniform radiation then greatly improves the interlayer adhesion.

The precursor plate configuration found most useful in this invention comprises a grained anodized aluminum substrate that is coated with a crosslinked hydrophilic inner layer formulation. An oleophilic surface layer formulation comprising an infrared radiation absorber is then applied. Further details of these constructions are provided below.

Further details of the advantages of the present invention will become apparent in consideration of the disclosure provided below.

### DETAILED DESCRIPTION OF THE INVENTION

### Definitions

Unless the context otherwise indicates, when used herein, the terms “positive-working lithographic printing plate precursor” and “lithographic printing plate precursor” are meant to be references to embodiments used or prepared in the practice of the present invention.

In addition, unless the context indicates otherwise, the various components described herein such as “non-crosslinked oleophilic polymer” “crosslinked polymeric binder”, and “infrared radiation absorber” also refer to mixtures of each component. Thus, the use of the articles “a”, “an”, and “the” is not necessarily meant to refer to only a single compound.

Unless otherwise indicated, percentages refer to percents by weight. Percent by weight can be based on the total solids in a formulation or composition, or on the total dry coating weight of a layer.

As used herein, the term “infrared radiation absorber” refers to compounds and materials that are sensitive to at least one wavelength of near infrared and infrared radiation and can convert photons into heat within the layer in which they are disposed. These compounds and materials can also be known in the art as “photothermal conversion materials”, “sensitizers”, or “light to heat convertors”.

For clarification of definition of any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any different definitions set forth herein should be regarded as controlling.

The term “polymer” refers to high and low molecular weight polymers including oligomers and can include both homopolymers and copolymers.

The term “copolymer” refers to polymers that are derived from two or more different monomers, or have two or more different types of recurring units, even if derived from the same monomer. Unless otherwise noted, the different constitutional recurring units are present in random order along the copolymer backbone.

The term “backbone” refers to the chain of atoms in a polymer to which a plurality of pendant groups are attached. An example of such a backbone is an “all carbon” backbone obtained from the polymerization of one or more ethylenically unsaturated polymerizable monomers. However, other backbones can include heteroatoms wherein the polymer is formed by a condensation reaction of some other means.

### Lithographic Printing Plate Precursors

The lithographic printing plate precursors are positive-working imageable elements so that the resulting lithographic printing plates have non-imaged (non-exposed) regions in the oleophilic surface layer only since the imaged (exposed) regions have been removed during processing. The remaining non-imaged (non-exposed) regions have an affinity or attraction for lithographic ink on the imaging surface while the underlying surfaces of the exposed regions have less affinity for the ink.

Substrates:

In their simplest form, the lithographic printing plate precursors are formed by suitable application of a hydrophilic inner layer formulation onto the substrate, which formulation is dried, and an oleophilic surface layer formulation is applied over the hydrophilic inner layer. This oleophilic surface layer formulation can also be generally considered to have the capability of absorbing infrared radiation, for example containing an infrared radiation absorber as described below. More details of these manufacturing steps are provided below. In most embodiments, the oleophilic surface layer and the crosslinked hydrophilic inner layer are the only essential layers in the precursors and are directly adhered to each other and the crosslinked hydrophilic inner layer is directly applied to the substrate.

The substrate can be treated or coated in various ways as described below prior to application of the hydrophilic inner layer formulation. For example, the substrate can be treated to provide a subbing layer for improved adhesion or hydrophilicity, and the hydrophilic inner layer formulation can be applied over this subbing layer.

The substrate generally has a hydrophilic surface, or a surface that is more hydrophilic than the applied formulations on the imaging side. The substrate comprises a support that can be composed of any material that is conventionally used to prepare imageable elements such as lithographic printing plates. It is usually in the form of a sheet, film, or foil, and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metallized papers), or a lamination of any of these materials (such as a lamination of an aluminum foil onto a polyester film). Metal-containing supports include sheets or foils of aluminum, copper, zinc, titanium, and alloys thereof.

Polymeric film supports can be modified on one or both surfaces with a “subbing” layer to enhance hydrophilicity, or paper supports can be similarly coated to enhance planarity. Examples of subbing layer materials include but are not limited to, alkoxysilanes, amino-propyltriethoxysilanes, glycidioxypropyl-triethoxysilanes, and epoxy functional polymers, as well as hydrophilic subbing materials such as gelatin and other naturally occurring and synthetic hydrophilic colloids and vinyl polymers including vinylidene chloride copolymers.

Useful substrates are aluminum-containing supports that can be coated or treated using techniques known in the art, including physical graining, electrochemical graining and chemical graining, followed by anodizing. The aluminum sheets are mechanically or electrochemically grained and anodized using phosphoric acid or sulfuric acid and conventional procedures.

An optional interlayer can be formed on the support by treating it with, for example, a silicate, dextrin, calcium zirconium fluoride, hexafluorosilicic acid, phosphate/sodium fluoride solution, poly(vinyl phosphonic acid) (PVPA), vinyl phosphonic acid copolymer, poly(acrylic acid), or acrylic acid copolymer solution, or an alkali salt of a condensed aryl sulfonic acid as described in GB 2,098,627 and Japanese Kokai 57-195697A (both Herting et al.). The grained and anodized aluminum support can be treated with poly(acrylic acid) using known procedures to improve surface hydrophilicity.

The thickness of the substrate can be varied but it should be sufficient to sustain the wear from printing and thin enough to wrap around a printing form.

The backside (non-imaging side) of the substrate can be coated with antistatic agents or slipping layer or matte layer to improve handling and “feel” of the imageable element.

The substrate can also be a cylindrical surface having the layers applied thereon, and thus be an integral part of the printing press. The use of such imaged cylinders is described for example in U.S. Pat. No. 5,713,287 (Gelbart).

Crosslinked Hydrophilic Inner Layer:

The crosslinked hydrophilic inner layer comprises one or more crosslinked hydrophilic materials, generally crosslinked hydrophilic polymeric binders. For example, such crosslinked hydrophilic polymeric binders can include but are not limited to, crosslinked poly(vinyl alcohol) for example having a hydrolysis value greater than 98%, crosslinked cellulosic resins, and crosslinked polyacrylic acids. Mixtures of these crosslinked polymeric binders can be used also. Such polymeric binders generally comprise at least 50 and up to and including 100 weight % of the crosslinked hydrophilic inner layer. The crosslinked hydrophilic inner layer dry coverage is generally at least 0.1 and up to and including 4 g/m² or typically at least 1 and up to and including 2 g/m².

The crosslinked hydrophilic polymeric binder is generally obtained using any suitable crosslinking agent, including but not limited to, the compounds that are selected from the group consisting of zirconium ammonium carbonate, ethane-1,2-dione, tetraethyl orthosilicate, tetramethyl orthosilicate, terephthalic aldehyde, and a melamine such as hexamethoxymethylmelamine that is available as Cymel® 303 crosslinking agent (Cytec Industries). Mixtures of these crosslinking agents can be used also. A skilled worker would understand how much crosslinking agent to use based on the amount of hydrophilic polymeric binder to be crosslinked in the formulation. In general, one or more crosslinking agents are provided in the hydrophilic inner layer formulation in an amount of at least 2 weight % and up to and including 50 weight %. Crosslinking of the one or more polymeric binders in the formulation generally occurs during the drying stage after the formulation is applied over the substrate, but additional crosslinking can occur during later steps, for example during the drying of successive layer formulations.

Sufficient crosslinking agent is generally present to also provide crosslinking at the interface of the crosslinked hydrophilic inner layer and the immediately overlying oleophilic surface layer.

The crosslinked hydrophilic layer can comprise at least 75 weight % of a poly(vinyl alcohol) that has been crosslinked with glyoxal.

The crosslinked hydrophilic inner layer can also include other addenda that would be useful for coating properties, adhesion to the underlying substrate, or adhesion to the overlying layer. Such addenda can include but are not limited to, silica, alumina, barium sulfate, titanium dioxide, kaolin, or other inorganic filler particles, and various surfactants. The inorganic filler particles can be present in an amount of at least 5 weight %. The crosslinked hydrophilic inner layer generally contains no infrared radiation absorbers as none of these materials is purposely incorporated into the crosslinked hydrophilic inner layer formulation and migration of such materials from the oleophilic surface layer is limited.

Oleophilic Surface Layer:

The lithographic printing plate precursor includes one or more non-crosslinked oleophilic polymers or polymeric binders that are considered the “primary” polymeric binders in the oleophilic surface (outermost) layer. The weight average molecular weight (M_{w}) of the useful primary polymeric binders is generally at least 5,000 and can be up to 500,000 and typically at least 10,000 and up to and including 100,000. The optimal M_{w} can vary with the specific polymer and its use.

Useful non-crosslinked oleophilic polymers include but are not limited to, any oleophilic polymer (including copolymers) such as phenolic resins including novolak and resole resins, poly(vinyl acetals), polyesters, polyvinyl aromatics (such as polystyrenes and poly(hydroxystyrenes)), that can be coated onto the crosslinked hydrophilic layer and that by suitable formulation will exhibit the desired adhesion characteristics to the underlying layer and also sufficient chemical resistance to the printing process. In general, the oleophilic polymers can be hardenable in the blanket exposing (described below) used after imaging and processing.

In most embodiments, the non-crosslinked oleophilic polymers are poly(vinyl acetal) resins that can comprise at least 15 mol % (based on total recurring units in resin) of randomly recurring units represented by the following Structure (Ia):

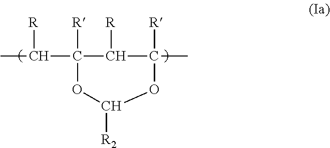

wherein R and R′ are independently hydrogen or a substituted or unsubstituted alkyl group (generally having 1 to 10 carbon atoms), a substituted or unsubstituted cycloalkyl group (having 5 to 10 carbon atoms in the ring structure), or a halo group (such as fluoro, chloro, or bromo). R₂ is an aryl group (such as phenyl, naphthyl, or anthryl) that is substituted with a cyclic imide group such as a cyclic aliphatic or aromatic imide group including but not limited to, maleimide, phthalimide, tetrachlorophthalimide, hydroxyphthalimide, carboxypthalimide, nitrophthalimide, chlorophthalimide, bromophthalimide, and naphthalimide groups. The aryl group of the cyclic aliphatic or aromatic imide group, or both the aryl and cyclic aliphatic or aromatic imide groups, are optionally further substituted with one or more substituents selected from the group consisting of hydroxyl, substituted or unsubstituted alkyl, substituted or unsubstituted alkoxy, and halo groups (such as fluoro and chloro), and any other group that does not adversely affect the properties of the cyclic imide group or the poly(vinyl acetal) in the oleophilic surface layer.

The poly(vinyl acetal) resins can further comprise randomly recurring units that are selected from one or more of the recurring units represented by the following Structures (Ib), (Ic), and (Id):

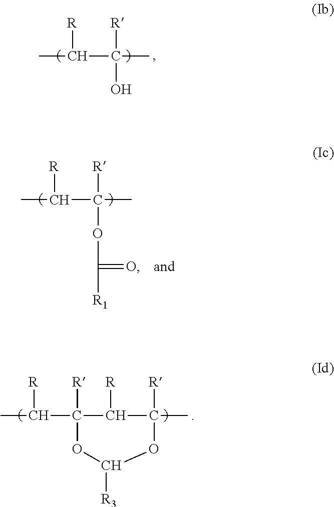

In all of these Structures, R and R′ are as defined above for Structure (Ia), but each recurring unit need not comprise the same R and R′ group as the other recurring units in the chain.

In Structure (Ic), R₁ is a substituted or unsubstituted linear or branched alkyl group having 1 to 12 carbon atoms (such as methyl, ethyl, n-propyl, n-butyl, n-pentyl, n-hexyl, chloromethyl, trichloromethyl, iso-propyl, iso-butyl, t-butyl, iso-pentyl, neo-pentyl, 1-methylbutyl, iso-hexyl, and dodecyl groups), a substituted or unsubstituted cycloalkyl having 5 to 10 carbon atoms in the carbocyclic ring (such as cyclopentyl, cyclohexyl, 4-methylcyclohexyl, and 4-chlorocyclohexyl), or a substituted or unsubstituted aryl group having 6 or 10 carbon atoms in the aromatic ring (such as phenyl, naphthyl, p-methylphenyl, and, p-chlorophenyl). Such groups can be substituted with one or more substituents such as alkyl, alkoxy, and halo, or any other substituent that a skilled worker would readily contemplate that would not adversely affect the performance of the polyvinyl acetal resin in the imageable element.

In Structure (Id), R₃ is an aryl group (such as phenyl, naphthyl, or anthracenyl group) that is unsubstituted or substituted with at least one hydroxy group and optionally a nitro group. Thus, R₃ can be a nitro-substituted phenol, nitro-substituted naphthol, or nitro-substituted anthracenol group, wherein the nitro group is generally in the meta-position relative to the aromatic carbon attached to the polymer backbone and the one or more hydroxy groups can be in the ortho, meta, or para positions relative to the aromatic carbon attached to the polymer backbone. The R₃ aryl group can have further substituents such as alkyl, alkoxy, or halo groups that do not adversely affect the properties of the aromatic group or the poly(vinyl acetal) in the oleophilic surface layer. R₃ is particularly a meta-nitro, ortho-phenol group relative to the aromatic carbon that is attached to the polymer backbone.

When recurring units represented by any of Structures (Ib), (Ic), and (Id) are present, in random order, the recurring units represented by Structure (Ib) can be present in an amount of at least 30 and up to and including 60 mol %, the recurring units represented by Structure (Ic) can be present in an amount of at least 1 and up to and including 15 mol %, and the recurring units represented by Structure (Id) can be present in an amount of at least 30 and up to and including 60 mol %, all based on the total recurring units in the poly(vinyl acetal).

The poly(vinyl acetal) resin can comprise the following recurring units, in random order, in the noted amounts, all based on the total recurring units in the resin:

Structure (Ia) recurring units of at least 20 and up to and including 100 mole %,

Structure (Ib) recurring units of at least 33 and up to and including 40 mol %,

Structure (Ic) recurring units of at least 2 and up to and including 5 mol %, and

Structure (Id) recurring units of at least 35 and up to and including 45 mol %.

The poly(vinyl acetal) resins useful in the oleophilic surface layer comprise at least recurring units represented by Structure (Ia) and optionally recurring units represented by Structures (Ib) through (Id) but such resins can also comprise randomly recurring units other than those defined by the illustrated recurring units and such additional recurring units would be readily apparent to a skilled worker in the art. Thus, the polymeric binders useful in this invention are not limited specifically to the recurring units defined by Structures (Ia) through (Id).

There also can be multiple types of recurring units from any of the defined classes of recurring units in Structures (Ia), (Ic), and (Id) with different substituents. For example, there can be multiple types of recurring units with different R and R′ groups, there can be multiple types of recurring units with different R₁ groups, there can be multiple types of recurring units with different R₂ groups, or there can be multiple types of recurring units with different R₃ groups. In addition, the number and type of recurring units in the primary polymeric binders are generally in random sequence, but blocks of specific recurring units can also be present unintentionally.

The primary polymeric binder is generally present in the oleophilic surface layer in an amount of at least 40 and up to and including 95 weight % (or typically at least 50 and up to and including 90 weight %) based on the total dry weight of the oleophilic surface layer.

The primary polymeric binders having pendant aryl groups (for example phenyl groups) that are substituted with a cyclic imide (such as a carboxy phthalimide group) on the aromatic ring can be prepared by acetalization of cyclic imide derivatives of aryl aldehydes with poly(vinyl alcohol) in the presence of acidic catalysts such as methanesulfonic acid in DMSO. For example, see the preparation of polymer MN24 below. Further details for preparing the poly(vinyl acetal) resins useful in this invention are provided in WO04/081662 (Memetea et al.) and U.S. Pat. Nos. 6,255,033, 6,541,181, and 7,723,012 (all Levanon et al.) that are incorporated herein by reference.

The primary polymeric binders described herein can be used alone or in admixture with other polymeric binders, identified herein as “secondary polymeric binders”. These additional polymeric binders include other poly(vinyl acetal)s that do not have recurring units represented by Structure (Ia). The type of the secondary polymeric binder that can be used together with the primary polymeric binder is not particularly restricted. Useful secondary polymeric binders include phenolic resins, including novolak resins such as condensation polymers of phenol and formaldehyde, condensation polymers of m-cresol and formaldehyde, condensation polymers of p-cresol and formaldehyde, condensation polymers of m-/p-mixed cresol and formaldehyde, condensation polymers of phenol, cresol (m-, p-, or m-/p-mixture) and formaldehyde, and condensation copolymers of pyrogallol and acetone. Further, copolymers obtained by copolymerizing compound comprising phenol groups in the side chains can be used.

Examples of other useful secondary polymeric binders include the following classes of polymers having an acidic group in (1) through (5) shown below on a main chain and/or side chain (pendant group).

(1) sulfone amide (—SO₂NH—R′),

(2) substituted sulfonamido based acid group (hereinafter, referred to as active imido group) [such as —SO₂NHCOR′, SO₂NHSO₂R′, —CONHSO₂R′],

(3) carboxylic acid group (—CO₂H),

(4) sulfonic acid group (—SO₃H), and

(5) phosphoric acid group (—OPO₃H₂).

R′ in the above-mentioned groups (1)-(5) represents hydrogen or a hydrocarbon group.

Other useful secondary polymeric binders include nitrocellulose, polyesters, and polystyrenes including poly(hydroxystyrenes).

The secondary polymeric binder can have a weight average molecular weight of at least 2,000 and a number average molecular weight of at least 500. Typically, the weight average molecular weight is at least 5,000 and up to and including 300,000, the number average molecular weight is at least 800 and up to and including 250,000, and the degree of dispersion (weight average molecular weight/number average molecular weight) is at least 1.1 and up to and including 10.

Mixtures of the secondary polymeric binders can be used with the one or more primary polymeric binders. The secondary polymeric binder(s) can be present in the oleophilic surface layer in an amount of at least 1 and up to and including 50 weight %, and typically at least 5 and up to and including 30 weight %.

The oleophilic surface layer typically also comprises one or more infrared radiation absorbers that are typically sensitive to infrared radiation of at least 700 nm and up to and including 1400 nm and typically at least 750 nm and up to and including 1250 nm.

Useful infrared radiation absorbers include pigments such as carbon blacks including but not limited to carbon blacks that are surface-functionalized with solubilizing groups are well known in the art. Carbon blacks that are grafted to hydrophilic, nonionic polymers, such as FX-GE-003 (manufactured by Nippon Shokubai), or which are surface-functionalized with anionic groups, such as CAB-O-JET® 200 or CAB-O-JET® 300 (manufactured by the Cabot Corporation) are also useful. Other useful carbon blacks are available from Cabot Billerica under the tradename Mogul. Other useful pigments include, but are not limited to, Heliogen Green, Nigrosine Base, iron (III) oxides, manganese oxide, Prussian Blue, and Paris Blue. The size of the pigment particles should not be more than the thickness of the oleophilic surface.

Examples of suitable IR dyes as infrared radiation absorbers include but are not limited to, azo dyes, squarylium dyes, croconate dyes, triarylamine dyes, thioazolium dyes, indolium dyes, oxonol dyes, oxazolium dyes, cyanine dyes, merocyanine dyes, phthalocyanine dyes, indocyanine dyes, indotricarbocyanine dyes, hemicyanine dyes, streptocyanine dyes, oxatricarbocyanine dyes, thiocyanine dyes, thiatricarbocyanine dyes, merocyanine dyes, cryptocyanine dyes, naphthalocyanine dyes, polyaniline dyes, polypyrrole dyes, polythiophene dyes, chalcogenopyryloarylidene and bi(chalcogenopyrylo)-polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, polymethine dyes, squarine dyes, oxazole dyes, croconine dyes, porphyrin dyes, and any substituted or ionic form of the preceding dye classes. Suitable dyes are described for example, in U.S. Pat. Nos. 4,973,572 (DeBoer), 5,208,135 (Patel et al.), 5,244,771 (Jandrue Sr. et al.), and 5,401,618 (Chapman et al.), and EP 0 823 327A1 (Nagasaka et al.).

Cyanine dyes having an anionic chromophore are also useful. For example, the cyanine dye can have a chromophore having two heterocyclic groups. In another embodiment, the cyanine dye can have from about two sulfonic acid groups, such as two sulfonic acid groups and two indolenine groups as described for example in U.S. Patent Application Publication 2005-0130059 (Tao).

Near infrared absorber cyanine dyes are also useful and are described for example in U.S. Pat. Nos. 6,309,792 (Hauck et al.), 6,264,920 (Achilefu et al.), 6,153,356 (Urano et al.), and 5,496,903 (Watanabe et al.). Suitable dyes can be formed using conventional methods and starting materials or obtained from various commercial sources including American Dye Source (Baie D'Urfe, Quebec, Canada) and FEW Chemicals (Germany). Other useful dyes for near infrared diode laser beams are described, for example, in U.S. Pat. No. 4,973,572 (noted above).

The infrared radiation absorbers are generally present in the oleophilic surface layer at a dry coverage of at least 2 and up to and including 30 weight %, or typically in an amount of at least 4 and up to and including 20 weight %. The particular amount needed for this purpose would be readily apparent to one skilled in the art, depending upon the specific compound used.

The oleophilic surface layer is generally directly disposed on the crosslinked hydrophilic layer and is weakly bonded to that at their interface by predominantly weak intermolecular bonds, mostly hydrogen bonding. Chemical bonding that is accomplished through covalent bonds, is generally absent or weakly present. While there can be crosslinking at the interface of the two layers, the oleophilic surface layer is generally non-crosslinked throughout. After exposing the processed imaged precursor to radiation (UV radiation or IR radiation or heat or a combination thereof) additional intermolecular bonds as well as stronger covalent bonds could be formed between the two layers at their interfaces, enhancing the adhesion between the two layers.

The oleophilic surface layer can also include one or more additional compounds that are colorant dyes, or UV or visible light-sensitive components. Useful colorant dyes include triarylmethane dyes such as ethyl violet, crystal violet, malachite green, brilliant green, Victoria blue B, Victoria blue R, and Victoria pure blue BO, BASONYL® Violet 610 and D11 (PCAS, Longjumeau, France). These compounds can act as contrast dyes that distinguish the non-exposed (non-imaged) regions from the exposed (imaged) regions in the lithographic printing plate. When a colorant dye is present in the oleophilic surface layer, its amount can vary widely, but generally it is present in an amount of at least 0.5 and up to and including 30 weight %.

The oleophilic surface layer can also include other addenda that would be useful for coating properties, coated layer physical properties, and adhesion to the underlying layer such as small organic molecules, oligomers, and surfactants. These additives can be generally present in the oleophilic surface layer in an amount of at least 1 and up to and including 30 weight %, or typically at least 2 and up to and including 20 weight %. The oleophilic surface layer can further include a variety of additives including dispersing agents, humectants, biocides, plasticizers, surfactants for coatability or other properties, viscosity builders, fillers and extenders, pH adjusters, drying agents, defoamers, preservatives, antioxidants, rheology modifiers or combinations thereof, or any other addenda commonly used in the lithographic art, in conventional amounts.

The oleophilic surface layer is generally present at a dry coverage of at least 0.7 and up to and including 2.5 g/m². In many embodiments, the dry coverage ratio of the oleophilic surface layer to the crosslinked hydrophilic layer is at least 0.4:1 and up to and including 2:1.

### Preparation of Lithographic Printing Plate Precursors

The positive-working lithographic printing plate precursors used in this invention can be prepared by applying a crosslinked hydrophilic inner layer formulation (as described above) in suitable solvents to the surface of the substrate (and any other hydrophilic layers provided thereon) using conventional coating or lamination methods. Thus, the crosslinked hydrophilic inner layer formulation can be applied by dispersing or dissolving the desired components (for example crosslinkable hydrophilic polymers and crosslinking agents) in one or more suitable coating solvents. The resulting formulation is applied to the substrate using suitable equipment and procedures, such as spin coating, knife coating, gravure coating, die coating, slot coating, bar coating, wire rod coating, roller coating, or extrusion hopper coating. The formulation can also be applied by spraying onto a suitable support (such as an on-press printing cylinder).

The crosslinked hydrophilic inner layer formulation can include at least 2% and up to and including 50% of one or more crosslinking agents. For example, the crosslinking agent can be selected from the group consisting of zirconium ammonium carbonate, ethane-1,2-dione, tetraethyl orthosilicate, tetramethyl orthosilicate, terephthalic aldehyde, and a melamine crosslinking agent. Mixtures of these crosslinking agents can also be used.

In certain embodiments, the inner layer formulation comprises a poly(vinyl alcohol) that is crosslinked during drying, for example that is crosslinked during the drying step using glyoxal, zirconium ammonium carbonate, ethane-1,2-dione, tetramethyl orthosilicate, or tetraethyl orthosilicate as a crosslinking agent.

After drying, the dry coating weight for the crosslinked hydrophilic inner layer is at least 0.1 and up to and including 4 g/m² and typically at least 1 and up to and including 2 g/m².

The selection of solvents used to coat the crosslinked hydrophilic inner layer formulation depends upon the nature of the hydrophilic polymeric binders, crosslinking agents, and other polymeric materials and non-polymeric components in the formulation. Generally, the crosslinked hydrophilic inner layer formulation is coated out of one or more solvents that can dissolve hydrophilic polymers including but not limited to, water, water-miscible alcohols, and ketones such as acetone, and mixtures thereof.

The oleophilic surface layer formulation is prepared by dissolving or dispersing the oleophilic polymer(s) such as a poly(vinyl acetal), any other polymeric binders, an infrared radiation absorber, and any other optional addenda in suitable solvents including but not limited to, acetone, methyl ethyl ketone, or another ketone, tetrahydrofuran, 1-methoxy-2-propanol, N-methylpyrrolidone, 1-methoxy-2-propyl acetate, γ-butyrolactone, and mixtures thereof using conditions and techniques well known in the art. After application of the formulation to the dried crosslinked hydrophilic inner layer, the oleophilic surface layer formulation is also dried to effect hydrogen bonding of the resulting oleophilic surface layer with the crosslinked hydrophilic inner layer.

Representative methods for preparing positive-working imageable elements are described below in the examples.

After all of the layer formulations are dried on the substrate (that is, the coatings are dry to the touch), the lithographic printing plate precursor can be heat treated at a temperature of at least 40° C. and up to and including 90° C. (typically of at least 50° C. and up to and including 70° C.) for at least 4 hours and typically for at least 20 hours. The maximum heat treatment time can be several days, but the optimal time and temperature for the heat treatment can be readily determined by routine experimentation. This heat treatment can also be known as a “conditioning” step. Such treatments are described for example, in EP 823,327 (Nagaska et al.) and EP 1,024,958 (McCullough et al.).

It can also be desirable that during the heat treatment, the lithographic printing plate precursor is wrapped or encased in a water-impermeable sheet material to represent an effective barrier to moisture removal from the precursor. This sheet material is sufficiently flexible to conform closely to the shape of the precursor (or stack of multiple precursors) and is generally in close contact with the precursors. For example, the water-impermeable sheet material can be sealed around the edges of the lithographic printing plate precursor(s). Such water-impermeable sheet materials include polymeric films or metal foils that are sealed around the edges of the precursors or stack thereof. More details of this process are provided in U.S. Pat. No. 7,175,969 (Ray et al.).

A stack of at least 10 and up to 1000 lithographic printing plate precursors can then be conditioned, stored, or shipped in appropriate containers for customer use.

### Imaging and Printing

The lithographic printing plate precursors used in this invention can have any useful form including, but not limited to, printing plate precursors, printing cylinder precursors, printing sleeve precursors and printing tape precursors (including flexible printing webs). In most embodiments, the invention is using lithographic printing plate precursors that are designed to form lithographic printing plates.

Lithographic printing plate precursors can be of any useful size and shape (for example, square or rectangular) having the requisite layers disposed on a suitable substrate. Printing cylinders and sleeves are known as rotary printing members having the substrate and requisite layers in a cylindrical form. Hollow or solid metal cores can be used as substrates for printing sleeves.

During use, the lithographic printing plate precursors are exposed to a suitable source of radiation such as near-IR and infrared radiation, depending upon the infrared radiation absorbing compound that can be present in the lithographic printing plate precursor, for example at a wavelength of at least 700 and up to and including 1500 nm. For most embodiments, imaging is carried out using an infrared or near-infrared laser at a wavelength of at least 700 and up to and including 1200 nm. The laser used to expose the imaging member can be a diode laser, because of the reliability and low maintenance of diode laser systems, but other lasers such as gas or solid-state lasers may also be used. The combination of power, intensity and exposure time for laser imaging would be readily apparent to one skilled in the art.

The imaging apparatus can function solely as a platesetter or it can be incorporated directly into a lithographic printing press. The imaging apparatus can be configured as a flatbed recorder or as a drum recorder, with the lithographic printing plate precursor mounted to the interior or exterior cylindrical surface of the drum. A useful imaging apparatus is available as models of Kodak Trendsetter imagesetters available from Eastman Kodak Company (Burnaby, British Columbia, Canada) that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen, Chicago, Ill.). Additional useful sources of radiation include direct imaging presses that can be used to image an element while it is attached to the printing plate cylinder. An example of a suitable direct imaging printing press includes the Heidelberg SM74-DI press (available from Heidelberg, Dayton, Ohio).

IR imaging exposure energy can be at least 100 J/cm², or typically at least 200 and up to and including 300 J/cm². A skilled worker in the art would know how to achieve the desired energy level using imaging rate, wattage, and other conditions in a suitable imager.

While laser imaging is usually practiced, imaging can be provided by any other means that provides thermal energy in an imagewise fashion. For example, imaging can be accomplished using a thermoresistive head (thermal printing head) in what is known as “thermal printing”, described for example in U.S. Pat. No. 5,488,025 (Martin et al.). Thermal print heads are commercially available (for example, as Fujitsu Thermal Head FTP-040 MCS001 and TDK Thermal Head F415 HH7-1089).

Imaging is generally carried out using direct digital imaging. The image signals are stored as a bitmap data file on a computer. Such data files may be generated by a raster image processor (RIP) or other suitable means. The bitmaps are constructed to define the hue of the color as well as screen frequencies and angles.

Imaging of the lithographic printing plate precursor produces a latent image of imaged (exposed) and non-imaged (non-exposed) regions. Substantially the entire oleophilic surface layer and perhaps a small portion of the crosslinked hydrophilic inner layer are weakened in the exposed regions.

The imaged precursor is then contacted or processed with water or any suitable developer having a pH of at least 4 and up to and including 14 but typically a pH of at least 6 and up to and including 10. Thus, mere water or weakly acidic or weakly alkaline solutions can be used to remove the oleophilic surface layer in the exposed regions leaving intact the oleophilic surface layer in the non-exposed regions. Such processing solutions can include nonionic or anionic surfactants, or both types of surfactants, chelating agents, salts, buffers, polar organic solvents, and other addenda commonly used in lithographic processing developers. Many of these processing solutions are described in the art and some are used commercially. In most embodiments, water or processing solutions containing at least 95 weight % of water are used. During this processing step, minimal amounts of the crosslinked hydrophilic inner layer are removed in the exposed regions. Thus, if any portion of this inner layer is removed, it is generally in the topmost part of the crosslinked hydrophilic inner layer that was closest to the oleophilic surface layer.

After the imaged precursor is processed to remove exposed regions of the oleophilic surface layer, the precursor is blanket (uniformly) exposed to radiation to increase adhesion of the crosslinked hydrophilic inner layer to the substrate as well as the adhesion of the non-exposed regions of the oleophilic surface layer to the crosslinked hydrophilic inner layer. For example, the radiation can be:

a) UV or IR radiation, or both UV and IR radiation,

b) heating at a temperature of at least 170° C. and up to and including 260° C. for at least 75 seconds and up to and including 2 hours, or

c) heating at a temperature of at least 170° C. and up to and including 260° C. for at least 75 seconds and up to and including 2 hours, and either or both of UV and IR radiation.

Suitable UV radiation can be supplied using a suitable mercury lamp, metal halide lamp, or Xenon flash lamp that provides at least 25 Watts per CM.

Suitable infrared (IR) radiation can be supplied using an IR heating lamp emitting either or both medium-wavelength infrared and short-wavelength infrared radiation, an IR laser, or infrared heater for at least 10 seconds that provides at least 25 Watts per cm. In particular, the infrared radiation source or emitter includes an infrared lamp, such as a short-wavelength infrared lamp that emits radiation at a wavelength of from 780 to 1400 nm. Such infrared lamps are available from Heraeus Noblelight (Germany). The temperature achieved by means of this infrared radiation treatment can generally be in the range at least 150° C. and up to and including 280° C. and the temperature can be controlled to be in the range of at least 170° C. and up to and including 260° C. Such control can be accomplished through testing based on radiation output, distance, or line speed, through a feedback loop involving, for example, temperature sensors and programmable controllers, or a combination thereof. In particular, the imaged and processed lithographic printing plate is not heated above an upper limit such that one or more of its materials are adversely affected (for example, buckling of the aluminum-containing substrate) and is not heated to below a lower limit such that insufficient adhesion between the two layers is obtained.

Heating can be carried out in an oven or other convection heating device under the noted conditions. An efficient oven is a Wisconsin oven in which the temperature and conveyor speed can be controlled.

After the blanket exposure, the resulting lithographic printing plate can be used for lithographic printing without additional contact with any solution, such as a rinsing solution or a gumming solution.

The imaged lithographic printing plates can be used for lithographic printing on any suitable printing apparatus using known fountain solutions and lithographic printing inks for as many impressions that are desired. The lithographic printing plate can be used in a single printing run for its entire printing life, or printing can be stopped and the printing plate cleaned before resuming lithographic printing.

The present invention provides at least the following embodiments and combinations thereof, but other combinations of features are considered to be within the present invention as a skilled artisan would appreciate from the teaching of this disclosure:

1. A method for providing a lithographic printing plate comprising:
providing a positive-working lithographic printing plate precursor comprising a hydrophilic substrate and having thereon:
   a crosslinked hydrophilic inner layer, and
   disposed over the crosslinked hydrophilic layer, an oleophilic surface layer comprising at least one non-crosslinked oleophilic polymer and an infrared radiation absorber in an amount of at least 2 weight %,
imagewise exposing the positive-working lithographic printing plate precursor with infrared radiation to form an imaged precursor with exposed regions and non-exposed regions in the oleophilic surface layer,
processing the imaged precursor to remove the oleophilic surface layer in the exposed regions, and
blanket exposing the imaged precursor to radiation.

2. The method of embodiment 1 comprising blanket exposing the imaged precursor to:
a) UV or IR radiation, or both UV and IR radiation,
b) heat at a temperature of at least 170° C. and up to and including 260° C. for at least 75 seconds and up to and including 2 hours, or
c) heat at a temperature of at least 170° C. and up to and including 260° C. for at least 75 seconds and up to and including 2 hours, and either or both of UV and IR radiation.

3. The method of embodiment 1 or 2 wherein the at least one non-crosslinked oleophilic polymer in the oleophilic surface layer is a poly(vinyl acetal) polymer.

4. The method of any of embodiments 1 to 3 wherein the at least one non-crosslinked oleophilic polymer in the oleophilic surface layer is a poly(vinyl acetal) polymer comprising at least 15 mol % recurring units, based on total recurring units, represented by the following Structure (Ia):

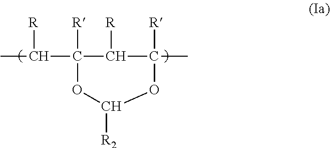

wherein R and R′ are independently hydrogen or a substituted or unsubstituted alkyl group, a substituted or unsubstituted cycloalkyl group, or halo group, and R₂ is an aryl group that is substituted with a cyclic imide group, which aryl or cyclic imide group can be further substituted.

5. The method of embodiment 4 wherein R₂ is a phenyl or naphthyl group that has a cyclic aliphatic or aromatic imide group selected from the group consisting of maleimide, phthalimide, tetrachlorophthalimide, hydroxyphthalimide, carboxyphthalimide, nitrophthalimide, chlorophthalimide, bromophthalimide, and naphthalimide groups, wherein the phenyl, naphthyl, or cyclic aliphatic or aromatic imide group is optionally further substituted with one or more substituents selected from the group consisting of hydroxyl, alkyl, alkoxy, and halo groups.

6. The method of embodiment 4 or 5 wherein the at least one non-crosslinked oleophilic polymer in the oleophilic surface layer is a poly(vinyl acetal) polymer further comprising randomly occurring recurring units represented by one or more of the following Structures (Ib) through (Id):

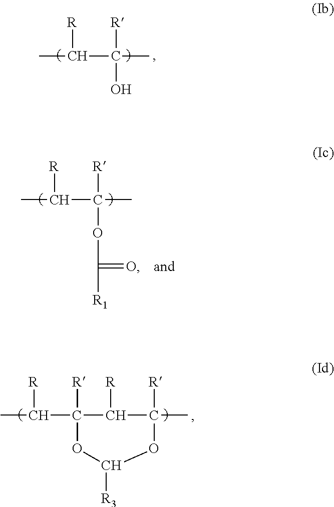

wherein R and R′ are independently hydrogen or a substituted or unsubstituted alkyl group, a substituted or unsubstituted cycloalkyl group, or a halo group,

R₁ is a substituted or unsubstituted linear or branched alkyl group having 1 to 12 carbon atoms, a substituted or unsubstituted cycloalkyl having 5 to 10 carbon atoms in the carbocyclic ring, or a substituted or unsubstituted aryl group having 6 or 10 carbon atoms in the aromatic ring, and

R₃ is an aryl group that is unsubstituted or substituted with at least one hydroxy group and optionally with a nitro group.

7. The method of embodiment 6 wherein R₃ is a nitro-substituted phenol, nitro-substituted naphthol, or a nitro-substituted anthracenol.

8. The method of any of embodiments 1 to 7 wherein the crosslinked hydrophilic inner layer comprises a crosslinked poly(vinyl alcohol), crosslinked cellulosic resin, crosslinked poly(meth)acrylic acid, or mixtures thereof.

9. The method of any of embodiments 1 to 8 wherein the crosslinked hydrophilic inner layer comprises a crosslinked poly(vinyl alcohol) obtained using zirconium ammonium carbonate, ethane-1,2-dione, tetramethyl orthosilicate, tetraethyl orthosilicate, terephthalic aldehyde, or a melamine, or mixtures thereof, as a crosslinking agent.

10. The method of any of embodiments 1 to 9 wherein the crosslinked hydrophilic inner layer further comprises inorganic filler particles in an amount of at least 5 weight %.

11. The method of any of embodiments 1 to 10 wherein the crosslinked hydrophilic inner layer comprises a crosslinked polymeric binder in an amount of at least 50 weight % and up to and including 100 weight %.

12. The method of any of embodiments 1 to 11 wherein the crosslinked hydrophilic inner layer has a dry coverage of at least 0.1 and up to and including 4 g/m².

13. The method of any of embodiments 1 to 12 wherein the crosslinked hydrophilic inner layer has a dry coverage of at least 1 and up to and including 2 g/m².

14. The method of any of embodiments 1 to 13 wherein the crosslinked hydrophilic inner layer comprises at least 75 weight % of a poly(vinyl alcohol) that has been crosslinked with glyoxal.

15. The method of any of embodiments 1 to 14 wherein the hydrophilic substrate comprises a hydrophilic aluminum support.

16. The method of any of embodiments 1 to 15 wherein the oleophilic surface layer is disposed directly on the crosslinked hydrophilic inner layer.

17. The method of any of embodiments 1 to 16 wherein the oleophilic surface layer has a dry coverage of at least 0.7 and up to and including 2.5 g/m².

18. The method of any of embodiments 1 to 17 wherein the dry coverage ratio of the oleophilic surface layer to the crosslinked hydrophilic layer is at least 0.4:1 and up to and including 2:1.

19. The method of any of embodiments 1 to 18 wherein the processing is carried out using water.

20. The method of any of embodiments 1 to 18 wherein the processing is carried out using a processing solution comprising at least 95 weight % of water.

21. The method of any of embodiments 1 to 20 further comprising: after the blanket exposing, using the lithographic printing plate having the image for lithographic printing without additional contact with a solution.

22. The method of any of embodiments 1 to 21 wherein the infrared radiation exposing is carried out at an energy level of at least 200 and up to and including 300 mJ/cm².

23. A lithographic printing plate obtained by the method of any of embodiments 1 to 22, the lithographic printing plate comprising a hydrophilic substrate and having thereon:
a crosslinked hydrophilic inner layer, and
disposed directly on the crosslinked hydrophilic layer, an oleophilic surface layer comprising non-exposed regions comprising at least one non-crosslinked oleophilic polymer and an infrared radiation absorber in an amount of at least 2 weight %, and exposed regions that are formed by removal of the oleophilic surface layer down to the crosslinked hydrophilic inner layer.

The following Examples are provided to illustrate the practice of this invention and are not meant to be limiting in any manner. In these examples, the following components were used to prepare the lithographic printing plate precursors. Unless otherwise indicated, the components are available from Aldrich Chemical Company (Milwaukee, Wis.):

BF-03 represents a poly(vinyl alcohol), 98% hydrolyzed (Mw=15,000) that was obtained from Chang Chun Petrochemical Co. Ltd. (Taiwan).

Celvol® 125 is a poly(vinyl alcohol), 99.3% hydrolyzed, average molecular weight 124,000 that can be obtained from Celanese Chemicals.

Crystal Violet is hexamethylpararosaniline.

DMSO represents dimethylsulfoxide.

Glyoxal solution is a 40 weight % solution of ethane-1,2-dione in water.

Keostrosol K 1530 is a 30% silica solution in water available from Chemiewerk Bad Kostritz GmbH.

MEK represents methyl ethyl ketone.

Mogul® L is a carbon black powder that can be obtained from Cabot (Billerica, Mass.).

MSA represents methanesulfonic acid (99%).

PM represents 1-methoxy-2-propanol, can be obtained as Arcosolve® available from LyondellBasell Industries (the Netherlands).

S 0094 is an infrared radiation absorbing dye (λₘₐₓ=813 nm) available from FEW Chemicals.

TEA represents triethanolamine.

A carboxy-substituted 4-phthalimidobenzaldehyde, IUPAC name 2-(4-formylphenyl)-1,3-dioxoisoindoline-5-carboxylic acid (Compound I) was prepared as follows:

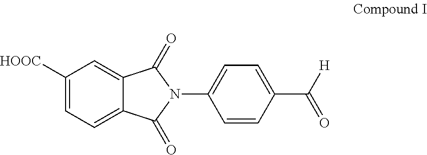

4-Aminobenzaldehyde (10 g) and 1,2,4-benzenetricarboxylic anhydride (15.86 g) were added to a 500 ml round bottom glass vessel equipped with a magnetic stirrer. Then, 350 g of acetic acid was added to the reaction vessel. The mixture was heated to the reflux while being stirred for 8 hours. The reaction mixture was chilled to room temperature. The precipitated product was filtered off, washed on the filter with water and alcohol, and dried. The yield of Compound I was 80% with a m.p. of 317° C.

Preparation of Polymer MN-24:

BF-03 (10.14 g) was added to a reaction vessel fitted with a water-cooled condenser, a dropping funnel and thermometer, containing DMSO (140 g). With continual stirring, the mixture was heated for 30 minutes at 80° C. until it became a clear solution. The temperature was then adjusted at 60° C. and MSA (0.88 g) was added. 2-(4-Formylphenyl)-1,3-dioxoisoindoline-5-carboxylic acid (10.00 g) in DMSO (20 g) was added to the reaction mixture and it was kept for 150 minutes at 85° C. Then, 2-hydroxy-5-nitro benzaldehyde (5-nitro-salicylic aldehyde, 8.87 g) and DMSO (20 g) were added to the reaction mixture that was then kept for 1 hour at 85° C. The reaction mixture was then diluted with DMSO (40 g) and anisole (55 g) and vacuum distillation was started. The anisole:water azeotrope was distilled out from the reaction mixture (less than 0.1% of water remained in the solution). The reaction mixture was chilled to room temperature and was neutralized with TEA (1 g) dissolved in DMSO (90 g), then blended with 1.8 kg of water. The resulting precipitated polymer was washed with water, filtered, and dried in vacuum for 24 hours at 60° C. to obtain 25.2 g of dry Polymer MN-24.

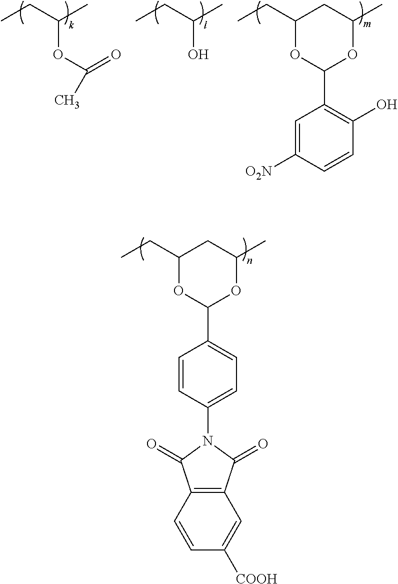

Recurring units in Polymer MN-24 in random order

The polymer binder MN-24 was derived from poly(vinyl alcohol) using 2% original acetate and its free OH groups were converted to acetals of carboxy substituted 4-phthalimidobenzaldehyde and 5-nitrosalicylic aldehyde at 30%, and 47%, respectively.

The lithographic printing plate precursors described for this invention comprised an infrared radiation-sensitive oleophilic surface layer coated onto a crosslinked hydrophilic inner layer that was applied to an anodized and chemically treated aluminum substrate as described below.

### Comparison Example 1

Lithographic printing plate precursors were prepared using the hydrophilic inner layer formulation containing the following components:

| Hydrophilic Inner Layer | Weight | Dry Weight |
|---|---|---|
| Formulation | (g) | % |
| Celvol ® 125 * poly(vinyl alcohol) | 34.795 | 94.44 |
| Glyoxal** | 0.205 | 5.56 |

* 4 weight % of PVA in water
**40 weight % of ethane-1,2-dione in water

This hydrophilic inner layer formulation was applied to an electrochemically roughened and anodized aluminum substrate that had been subjected to post-treatment with an aqueous solution of sodium phosphate/sodium fluoride using known procedures and the coating was dried for 4 minutes at 140° C. in an oven to provide a dry coating weight of about 1.7 g/m². Onto this dried layer was coated an oleophilic surface layer formulation that was prepared by milling for 3 days (with metal balls) the following components (of Part A) that were then diluted before coating with the solvents mixture of part B:

| Oleophilic Surface Layer | | |
|---|---|---|
| Formulation | Weight (g) | Dry Weight % |
| Part A - Milled base | | |
| Polymer MN-24 | 4.053 | 65 |
| MEK | 8.709 | 0 |
| PM | 16.175 | 0 |
| Mogul ® L carbon black | 2.182 | 35 |
| Part B - Solvents added to | | |
| Part A after milling | | |
| MEK | 1.004 | 0 |
| PM | 1.864 | 0 |

The oleophilic surface layer formulation was dried for 4 minutes at 170° C. in an oven to provide a dry coating weight of about 1.5 g/m².

The resulting lithographic printing plate precursor was exposed on a Kodak® Lotem 400 Quantum imager in a range of energies of 100 mJ/cm² to 300 mJ/cm² and cleaned with water. The background could be cleaned when exposure was at 200 mJ/cm². Even at an exposure at 100 mJ/cm², the background can be cleaned. However, cleaning must be sufficiently rigorous that there is a danger that small features may be removed. An exposure at 300 mJ/cm² was determined to be the correct exposure as after cleaning, the small features remain undamaged. The imaged lithographic printing plate precursor was then mounted onto a Ryobi 520HX printing press and 5,000 impressions were made. Signs of wear, of the fine features in particular (10% dots at 200 lpi screen) were seen starting from several hundred of impressions.

### Invention Example 1

Lithographic printing plate precursors were prepared as described in Comparison Example 1, but the imaged and water-processed printing plates were heated in an oven for 2 hours at 170° C. The lithographic printing plate was then mounted on a Ryobi 520HX press and 20,000 impressions were made. Signs of wear, of fine features in particular (10% dots at 200 lpi screen), were seen starting from about 20,000 impressions. Thus, the heating step after imaging and processing significantly improved the printing run length compared to the lithographic printing plate of Comparison Example 1.

### Invention Example 2

Lithographic printing plate precursors were prepared as described in Comparison Example 1, but the imaged and water-processed printing plates were heated with a shortwave IR lamp for 15 seconds. This lamp generates 60 Watts/cm and was placed about 5 cm above the lithographic printing plate. The lithographic printing plate was then mounted on a Ryobi 520HX press and 20,000 impressions were made. Signs of wear, of fine features in particular (10% dots at 200 lpi screen), were seen starting from about 15,000 impressions. Thus, the IR irradiation step after imaging and processing significantly improved the printing run length compared to the lithographic printing plate of Comparison Example 1. Moreover, the IR irradiation step is faster than the heating step used in Invention Example 1.

### Comparison Example 2

Lithographic printing plate precursors were prepared as described above in Comparison Example 1 but the following oleophilic surface layer formulation was used to form the imageable oleophilic surface layer:

| Oleophilic Surface Layer Formulation | Weight (g) | Dry Weight % |
|---|---|---|
| Polymer MN-24 | 2.476 | 94 |
| MEK | 9.578 | 0 |
| PM | 17.788 | 0 |
| IR dye S 0094 | 0.105 | 4 |
| Crystal Violet | 0.053 | 2 |

The oleophilic surface layer formulation described above was applied and dried for 4 minutes at 170° C. in an oven to provide a dry coverage of about 1.3 g/m².

The resulting lithographic printing plate precursor was exposed using a Kodak® Lotem 400 Quantum imager in a range of energies of 100 mJ/cm² to 300 mJ/cm² and cleaned with water. The background could be cleaned when the exposure was at 200 mJ/cm². Even exposing at 100 mJ/cm², the background could be cleaned. However, cleaning must be sufficiently rigorous that there is a danger that small features may be removed. An exposure at 300 mJ/cm² was determined to be the correct exposure as after water cleaning the small features may remain undamaged. The imaged precursor was then mounted onto a Ryobi 520HX press and 5,000 impressions were made, but good image quality was observed only in the first few impressions. Soon thereafter, image wear on the press became significant in the fine features in particular (10% dots at 200 lpi screen).

### Invention Example 3

Lithographic printing plate precursors were prepared as described above in Comparison Example 2. The imaged and water-processed printing plates were heated in an oven for 2 hours at 170° C. The lithographic printing plate was then mounted on a Ryobi 520HX press and 40,000 impressions were made without signs of wear of fine features in particular (10% dots at 200 lpi screen). Thus, the heating step after imaging and water processing significantly improved the printing run length compared to the lithographic printing plate of Comparison Example 2.

### Invention Example 4

Lithographic printing plate precursors were prepared as described above in Comparison Example 2. The imaged and water-processed printing plates were heated with a shortwave IR lamp for 25 seconds. This lamp generates 60 Watts/cm and was placed about 5 cm above the lithographic printing plate. The lithographic printing plate was then mounted on a Ryobi 520HX press and 30,000 impressions were made without signs of wear of fine features in particular (10% dots at 200 lpi screen). Thus, the irradiation step after imaging and water processing significantly improved the printing run length compared to the lithographic printing plate of Comparison Example 2.

Moreover, the IR irradiation step is faster than the heating step used in Invention Example 3.

### Comparison Example 3

Lithographic printing plate precursors were prepared as described above in Comparison Example 2 but the following hydrophilic inner layer formulation was used to form the crosslinked hydrophilic inner layer:

| Hydrophilic Inner Layer | Weight | Dry |
|---|---|---|
| Formulation | (g) | Weight % |
| Celvol ® 125* poly(vinyl alcohol) | 15.648 | 84.37 |
| Glyoxal** | 0.104 | 5.62 |
| Keostrosol K 1530 | 0.247 | 10 |

*4 weight % of PVA in water
**40 weight % of ethane-1,2-dione in water

The hydrophilic inner layer formulation was applied and dried for 4 minutes at 140° C. in an oven to provide a dry coverage of about 1.8 g/m². The oleophilic surface layer formulation of Comparison Example 2 was applied and dried for 4 minutes at 170° C. in an oven to provide a dry coverage of about 1.3 g/m².

The resulting lithographic printing plate precursor was exposed onto a Kodak® Lotem 400 Quantum imager in a range of energies of 150 mJ/cm² to 500 mJ/cm² and cleaned with water. The background could be cleaned when exposure was at 300 mJ/cm². Even at exposure at 150 mJ/cm², the background can be cleaned. However, cleaning must be sufficiently rigorous that there is a danger that small features may be removed. An exposure at 450 mJ/cm² was determined to be the correct exposure as the small features remained undamaged after water cleaning. The imaged precursor was then mounted onto a Ryobi 520HX press and 5,000 impressions were made. Signs of wear of fine features in particular (10% dots at 200 lpi screen) were seen at about 1000 impressions. Thus, the presence of the Keostrosol K 1530 silica improved the adhesion between the two layers, and hence the improved run length (compared with Comparison Example 2). However, the lithographic printing plate precursor was less sensitive than that of Comparison Example 2.

### Invention Example 5

Imageable elements were prepared as described in Comparison Example 3 but the lithographic printing plate was heated in an oven after imaging and water cleaning, for 2 hours at 170° C. The lithographic printing plate was then mounted on a Ryobi 520HX press and 60,000 impressions were made. Signs of wear of the fine features particularly (10% dots at 200 lpi screen) were seen at about 50,000 impressions. Thus, the addition of the Keostrosol K 1530 silica improved the adhesion between the two layers, and hence improved the run length compared with the lithographic printing plate of Invention Example 3. In addition, the heating step also significantly improved the printing run length.

### Invention Example 6

Imageable elements were prepared as described in Comparison Example 3. The lithographic printing plate was also heated after the imaging and water cleaning with a short wave IR lamp for 15 seconds. This IR lamp generates 60 Watts/cm and was placed at about 5 cm above the imaged printing plate surface. The lithographic printing plate was then mounted on a Ryobi 520HX press and 20,000 impressions were made without wear of fine feature areas (10% dots at 200 lpi screen). Thus, the heating step significantly improved the printing run length. The heating step was made much faster by using the short wave IR lamp compared to heating with an oven as in Invention Example 5.

### Invention Example 7

Lithographic printing plate precursors were prepared as described above in Comparison Example 2. The imaged and water-processed lithographic printing plates were heated in an oven for 75 seconds at 260° C. A lithographic printing plate was then mounted on a Ryobi 520HX press and 35,000 impressions were made without signs of wear of fine features in particular (10% dots at 200 lpi screen). Thus, as in Invention Example 3, the heating step after imaging and water processing significantly improved the printing run length compared to the lithographic printing plate of Comparison Example 2. In addition, the results demonstrated that increasing the post heating temperature from 170° C. (as in Invention Example 3) to 260° C. allowed a significant reduction in the heating time, that is from 2 hours in Invention Example 3 to 75 seconds in this example while still obtaining desirable print run length.

### Invention Example 8

Lithographic printing plate precursors were prepared as described above in Comparison Example 2 but the crosslinked hydrophilic inner layer formulation was dried for 1 minute at 120° C. in an oven. An exposure at 250 mJ/cm² was determined to be the correct exposure as after cleaning with water, the small image features remain undamaged. As in Invention Example 7, the imaged and water-processed lithographic printing plates were heated in an oven for 75 seconds at 260° C. A lithographic printing plate was then mounted on a Ryobi 520HX press and 40,000 impressions were made without signs of wear of fine features in particular (10% dots at 200 lpi screen). Thus, reducing the drying duration and temperature of the coated hydrophilic layer, from 4 minutes at 140° C. (in Comparison Example 2 and Invention Example 7) to 1 minute at 120° C. allowed a reduction in the imaging energy needed at which the small features remain undamaged after cleaning with water. Moreover, the reduced drying duration and temperature used for the crosslinked hydrophilic inner layer in this case provided improved print run length compared to that obtained in Invention Example 7.

### Solvent Resistance of the Lithographic Printing Plate Precursors:

Polymer MN-24 can be dissolved in PM or in a PM:MEK mixture that is used in oleophilic surface layer formulations. However, coatings obtained using this polymer is not soluble with PM.

The resistance to press chemicals of the lithographic printing plate precursors prepared in Invention Examples 1 and 3 and of several comparative precursors were evaluated using the following tests:

Solvent Resistance Tests:

Four solvent mixtures were used for these tests:

(1) Butyl Cellosolve (“BC”, 2-butoxyethanol) test, 80% in water

(2) UV Wash test (“Glycol Ether” blends)

(3) Diacetone Alcohol test (“DAA”, 80% in water)

(4) Heatset Fountain Solution E9069/3 test at two different concentrations, 100% and 8% in water. Heatset Fountain Solution E9069/3 is commercial product that comprises 2-(2-butoxyethoxy)ethanol, Bronopol™ antimicrobial that comprises 2-bromo-2-nitropropane-1,3-diol, ethanediol, and propan-2,1-diol.

For each test, drops of the each solvent mixture was placed on a 100% solid region and also on a 30% screen (200 lpi) region of the imaged, water-washed, and post-heated (for 2 hours at 170° C.) lithographic printing plates, and then the drops were removed with a cloth. Each test was carried out at about 23° C. The dot size before and 20 minutes after the solvent contact was measured using a spectroplate. After the solvent drops were on the precursors for 20 minutes, each imaged precursors was then mounted onto a Ryobi 520HX printing press and 5000 impressions were made to see if the dots remained on the lithographic printing plates.

Excellent solvent resistance was found for the lithographic printing plate precursors prepared in Invention Examples 1 and 3 and for a single-layer precursor having only the oleophilic surface layer described in Comparison Example 1 that had been coated directly onto aluminum substrate (as described in Table 1 below) for all solvent mixtures used in the evaluations. The results show that the compositions containing the primary binder polyvinyl acetal containing the carboxy-substituted phthalimide acetal recurring unit “n” shown in Scheme 1 above within the scope of this invention provided lithographic printing plate precursors with excellent solvent resistance to a broad range of press chemicals. In addition, the presence of the carboxy-substituted phthalimide acetal recurring units was found to be very efficient in making the lithographic printing plates resistant to the press solvents. The solvent resistance tests were not performed on the lithographic printing plate precursors prepared in Invention Examples 2 and 4-8 but the lithographic printing plates obtained in those examples showed desirable print run length, which is also indicative of solvent resistance.

A test was developed to clearly distinguish suitable formulations from unsuitable formulations by using a Crockmeter as a means of rub testing (see ASTM D3181) with water (wet) on a rubbing cloth (see TABLE I below). The adhesion of the oleophilic surface layer to either the crosslinked hydrophilic inner layer or to the aluminum-containing substrate was evaluated.

TABLE I

| Lithographic Printing Plate Precursor | Comments |
|---|---|
| Comparison Example 1 that had not been | Signs of coating wear at |
| imaged | 7-9 wet rubs and significant |
| | coating wear at 20 wet rubs. |
| Comparison Example 1 that had not been | Very weak signs of coating |
| imaged but was heated for 2 hours at | wear at 20 wet rubs and some |
| 170° C. in an oven. | coating wear at 100 wet rubs. |
| Comparison Example 1 that had been | Significant coating wear |
| laser imaged at 200 mJ/cm²* | at 10 wet rubs. |
| Comparison Example 1 that had been | Complete coating removal |
| laser imaged at 300 mJ/cm²* | at 6 wet rubs. |
| Comparison Example 1 that had been | Complete coating removal |
| laser imaged at 400 mJ/cm²* | at 4 wet rubs. |
| Single-layer precursor with oleophilic | No coating wear observed |
| surface layer of Comparison Example 1 | after 100 wet rubs. |
| that was coated directly onto the | |
| aluminum substrate and dried for 1 | |
| minute at 100° C. in an oven. The | |
| precursor was not imaged. | |
| Commercially available Kodak ® Electra | No coating wear observed |
| XD that had not been imaged. | after 100 wet rubs. |
| Commercially available Presstek | Very weak signs coating wear |
| Anthem that had not been imaged in a | at 60 wet rubs and some |
| CTP. | coating wear at 100 wet rubs. |

*A Kodak ® Thermo Flex 400 CTP imager was used for imaging. This imager generates a less efficient laser beam compared to the Kodak ® Lotem 400 Quantum imager.

The results shown in TABLE I indicate that while interlayer adhesion should be so weak that visible damage to the coating can be seen at approximately seven to nine rubs, the adhesion must be sufficient to retain the non-exposed (non-imaged) regions of coating during water processing (development) stage when the exposed regions are removed by water processing. When the coatings are heated, no wear should be seen for at least fifty rubs. If the oleophilic surface layer formulation is directly coated onto the anodized aluminum, it will sustain 100 rubs without wear. Thus the heating step after imaging and processing is an amplification step.

The chemical and physical characteristics of the precursors used in this invention can be optimized using the teaching provided in this application. Various factors can be used to strengthen or weaken the adhesion between the oleophilic surface layer and the crosslinked hydrophilic inner layer. For example, a rougher or smoother coating surface will increase or decrease adhesion between the two layers, respectively. For example, adding non-reactive particulate additives such as silica to the crosslinked hydrophilic inner layer could increase its surface roughness and strengthen its adhesion to the oleophilic surface layer above it. Other useful factors to increase adhesion between the two layers include the chemical composition, structure and functional groups present in both layers, for example the presence of hydroxyl groups on the polymeric binders would likely improve adhesion through hydrogen bonding. Also, the type of crosslinking agent used can affect interlayer adhesion. It could be that a crosslinking agent that is present in one layer can react with the surface of the second layer. An additional factor is the drying temperature and duration used for each coated layer during manufacture of the lithographic printing plate precursor, for example using higher temperatures or heating times, or both, when drying the oleophilic surface layer formulation can improve the adhesion between the two layers.

Furthermore, the thickness of each layer could influence the lithographic printing plate precursor sensitivity. For example, thicker hydrophilic layers can be more efficient thermal insulators and increase the precursor sensitivity.

All of these factors can be adjusted by routine experimentation so that the interlayer adhesion is sufficiently strong to withstand the processing after imaging, but at the same time provide sufficiently weak interlayer adhesion to allow high precursor sensitivity during imaging. Once the imaged and processed precursor is blanket exposed to radiation or heating, the lithographic printing plate should be useful for many impressions without wear particularly in the fine details.

The invention has been described in detail with particular reference to certain preferred embodiments thereof, but it will be understood that variations and modifications can be effected within the spirit and scope of the invention.

1. A method for providing a lithographic printing plate comprising:
providing a positive-working lithographic printing plate precursor comprising a hydrophilic substrate and having thereon:
a crosslinked hydrophilic inner layer, and
disposed over the crosslinked hydrophilic layer, an oleophilic surface layer comprising at least one non-crosslinked oleophilic polymer and an infrared radiation absorber in an amount of at least 2 weight %,
imagewise exposing the positive-working lithographic printing plate precursor with infrared radiation to form an imaged precursor with exposed regions and non-exposed regions in the oleophilic surface layer,
processing the imaged precursor to remove the oleophilic surface layer in the exposed regions, and
blanket exposing the imaged precursor to radiation.

2. The method of claim 1 comprising blanket exposing the imaged precursor to:
a) UV or IR radiation, or both UV and IR radiation,
b) heat at a temperature of at least 170° C. and up to and including 260° C. for at least 75 seconds and up to and including 2 hours, or
c) heat at a temperature of at least 170° C. and up to and including 260° C. for at least 75 seconds and up to and including 2 hours, and either or both UV and IR radiation.

3. The method of claim 1 wherein the at least one non-crosslinked oleophilic polymer in the oleophilic surface layer is a poly(vinyl acetal) polymer.

4. The method of claim 1 wherein the at least one non-crosslinked oleophilic polymer in the oleophilic surface layer is a poly(vinyl acetal) polymer comprising at least 15 mol % recurring units, based on total recurring units, represented by the following Structure (Ia): 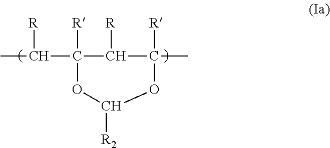
wherein R and R′ are independently hydrogen or a substituted or unsubstituted alkyl group, a substituted or unsubstituted cycloalkyl group, or halo group, and R₂ is an aryl group that is substituted with a cyclic imide group, which aryl or cyclic imide group can be further substituted.

5. The method of claim 4 wherein R₂ is a phenyl or naphthyl group that has a cyclic aliphatic or aromatic imide group selected from the group consisting of maleimide, phthalimide, tetrachlorophthalimide, hydroxyphthalimide, carboxyphthalimide, nitrophthalimide, chlorophthalimide, bromophthalimide, and naphthalimide groups, wherein the phenyl, naphthyl, or cyclic aliphatic or aromatic imide group is optionally further substituted with one or more substituents selected from the group consisting of hydroxyl, alkyl, alkoxy, and halo groups.

6. The method of claim 4 wherein the at least one non-crosslinked oleophilic polymer in the oleophilic surface layer is a poly(vinyl acetal) polymer further comprising randomly occurring recurring units represented by one or more of the following Structures (Ib) through (Id): 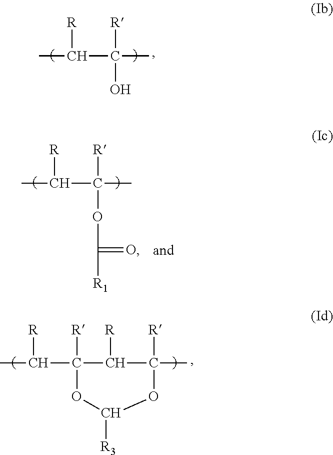
wherein R and R′ are independently hydrogen or a substituted or unsubstituted alkyl group, a substituted or unsubstituted cycloalkyl group, or a halo group,
R₁ is a substituted or unsubstituted linear or branched alkyl group having 1 to 12 carbon atoms, a substituted or unsubstituted cycloalkyl having 5 to 10 carbon atoms in the carbocyclic ring, or a substituted or unsubstituted aryl group having 6 or 10 carbon atoms in the aromatic ring, and
R₃ is an aryl group that is unsubstituted or substituted with at least one hydroxy group and optionally with a nitro group.

7. The method of claim 6 wherein R₃ is a nitro-substituted phenol, nitro-substituted naphthol, or a nitro-substituted anthracenol.

8. The method of claim 1 wherein the crosslinked hydrophilic inner layer comprises a crosslinked poly(vinyl alcohol), crosslinked cellulosic resin, crosslinked poly(meth)acrylic acid, or mixtures thereof.

9. The method of claim 1 wherein the crosslinked hydrophilic inner layer comprises a crosslinked poly(vinyl alcohol) obtained using zirconium ammonium carbonate, ethane-1,2-dione, tetramethyl orthosilicate, tetraethyl orthosilicate, terephthalic aldehyde, or a melamine, or mixtures thereof, as a crosslinking agent.

10. The method of claim 1 wherein the crosslinked hydrophilic inner layer further comprises inorganic filler particles in an amount of at least 5 weight %.

11. The method of claim 1 wherein the crosslinked hydrophilic inner layer comprises a crosslinked polymeric binder in an amount of at least 50 weight % and up to and including 100 weight %.

12. The method of claim 1 wherein the crosslinked hydrophilic inner layer has a dry coverage of at least 0.1 and up to and including 4 g/m².

13. The method of claim 1 wherein the crosslinked hydrophilic inner layer has a dry coverage of at least 1 and up to and including 2 g/m².

14. The method of claim 1 wherein the crosslinked hydrophilic inner layer comprises at least 75 weight % of a poly(vinyl alcohol) that has been crosslinked with glyoxal.

15. The method of claim 1 wherein the hydrophilic substrate comprises a hydrophilic aluminum support.

16. The method of claim 1 wherein the oleophilic surface layer is disposed directly on the crosslinked hydrophilic inner layer.

17. The method of claim 1 wherein the oleophilic surface layer has a dry coverage of at least 0.7 and up to and including 2.5 g/m².

18. The method of claim 1 wherein the dry coverage ratio of the oleophilic surface layer to the crosslinked hydrophilic layer is at least 0.4:1 and up to and including 2:1.

19. The method of claim 1 wherein the processing is carried out using water.

20. The method of claim 1 wherein the processing is carried out using a processing solution comprising at least 95 weight % of water.

21. The method of claim 1 further comprising:
after the blanket exposing, using the lithographic printing plate having the image for lithographic printing without additional contact with a solution.

22. The method of claim 1 wherein the infrared radiation exposing is carried out at an energy level of at least 200 and up to and including 300 mJ/cm².

23. A lithographic printing plate obtained by the method of claim 1, the lithographic printing plate comprising a hydrophilic substrate and having thereon:
a crosslinked hydrophilic inner layer, and
disposed directly on the crosslinked hydrophilic layer, an oleophilic surface layer comprising non-exposed regions comprising at least one non-crosslinked oleophilic polymer and an infrared radiation absorber in an amount of at least 2 weight %, and exposed regions that are formed by removal of the oleophilic surface layer down to the crosslinked hydrophilic inner layer.
